(19) United States
(12) Patent Application Publication
(10) Pub. No.: US 2024/0232471 A9
(43) Pub. Date: Jul. 11, 2024

(54) SYSTEMS AND METHODS OF PROVIDING A CUTTING DIE

(71) Applicants: Merrick LEVENE, Kitchener (CA); Michael R. GEFFROS, Kitchener (CA); Wesley Elton SCOTT, Kitchener (CA); ONTARIO DIE INTERNATIONAL INC., Kitchener (CA)

(72) Inventors: Merrick LEVENE, Kitchener (CA); Michael R. GEFFROS, Kitchener (CA); Wesley Elton SCOTT, Kitchener (CA)

(21) Appl. No.: 18/547,994

(22) PCT Filed: Feb. 24, 2022
(86) PCT No.: PCT/CA2022/050259

§ 371 Date: Aug. 25, 2023

Related U.S. Application Data
(60) Provisional application No. 63/154,155, filed on Feb. 26, 2021.

(51) Int. Cl. G06F 30/20

(52) U.S. Cl. CPC G06F 30/20; B26F 1/44

(57) ABSTRACT

Systems and methods of generating an image of a modified desired cutting die are described herein. One image of a desired cutting die is received; an entire cutting edge of the desired cutting die in the image is identified, an image of a modified desired cutting die based on the offset distance and desired tolerance is generated. By using the systems and methods, The amount of material used to create a plurality of pieces of the material with a cutting machine is reduced.

### CROSS-REFERENCE TO RELATED APPLICATION

This application claims the benefit of U.S. Provisional Patent Application No. 63/154,155, filed Feb. 26, 2021, and the entire content of U.S. Provisional Patent Application No. 63/154,155 is hereby incorporated by reference.

### FIELD

The specification relates generally to systems and methods for providing dies, and more specifically to systems and methods for providing dies within a defined tolerance.

### BACKGROUND

Cutting dies are typically made from edge-sharpened strip metal such as but not limited to steel and may be manufactured to have complex shapes created by a series of two-dimensional bends of, for example, steel rule stock. Each bend within the cutting die is at a precise angle and at a precise location along the length of the rule stock.

Steel rule cutting dies offer advantages over other technologies, such as but not limited to laser cutting, to those looking to cut materials and/or fabrics. For instance, because of the strength of steel, cutting dies made from steel rule stock can be used hundreds or thousands of times to cut materials and/or fabrics into consistent and predicable shapes.

Unfortunately, because of the strength of steel rule stock, the manufacture of steel rule stock cutting dies can be a complex process. When designing a desired cutting die, designers typically require that the shape of the manufactured cutting die be within a pre-determined tolerance. Ensuring that the shape of the manufactured cutting die falls within the pre-determined tolerance can be difficult

Accordingly, new and improved methods of providing a cutting die, and specifically, new and improved methods of providing a cutting die within a pre-determined tolerance are desired.

### SUMMARY

The following summary is intended to introduce the reader to various aspects of the applicant's teaching, but not to define any invention.

According to a broad aspect, a system for generating an image of a modified desired cutting die is described herein. The system includes at least one data storage device storing a set of cutting edge specifications; and at least one processor communicatively coupled to the at least one data storage device. The at least one processor is operable to: receive at least one image of a desired cutting die; identify an entire cutting edge of the desired cutting die as shown in the least one image of the desired cutting die, the cutting edge being positioned around a perimeter of the cutting die; identify at least one feature of the cutting edge of the desired cutting die as shown in the least one image of the desired cutting die; retrieve a set of cutting edge specifications from the data storage device, the set of cutting edge specifications including a desired tolerance for differences between a shape of the desired cutting die and a shape of a provided cutting die; based the on the desired tolerance, calculate an offset distance between the cutting edge of the desired cutting die and a cutting edge of the provided cutting die; and generate an image of a modified desired cutting die based on the offset distance.

In at least one embodiment, the processor is operable to, when generating the image of the modified desired cutting die, apply the offset distance to the cutting edge of the desired cutting die such that the shape of the modified desired cutting die is smaller than the shape of the desired cutting die.

In at least one embodiment, the processor is operable to, when generating the image of the modified desired cutting die, modify a position of the one or more features of the cutting edge of the desired cutting die based on the desired tolerance.

In at least one embodiment, the processor is operable to, when generating the image of the modified desired cutting die, modify a position of the one or more features of the cutting edge of the desired cutting die based on the offset distance.

In at least one embodiment, the processor is operable to, when generating the image of a modified desired cutting die, modify a feature of the cutting edge of the desired cutting die based on one or more of the offset distance and the desired tolerance.

In at least one embodiment, the offset distance is less than the desired tolerance.

In at least one embodiment, the offset distance is less than about 75% of the desired tolerance, or less than about 60% of the desired tolerance, or about 50% of the desired tolerance.

In at least one embodiment, the offset distance is greater than the desired tolerance.

According to another broad aspect, a system for providing a cutting die is described herein. The system includes at least one data storage device storing a set of cutting edge specifications; and at least one processor communicatively coupled to the at least one data storage device, the at least one processor operable to: receive at least one image of a desired cutting die; identify an entire cutting edge of the desired cutting die as shown in the least one image of the desired cutting die, the cutting edge being positioned around a perimeter of the cutting die; identify at least one feature of the cutting edge of the desired cutting die as shown in the least one image of the desired cutting die; retrieve a set of cutting edge specifications from the data storage device, the set of cutting edge specifications including a desired tolerance for differences between a shape of the desired cutting die and a shape of a provided cutting die; based the on the desired tolerance, calculate an offset distance between the cutting edge of the desired cutting die and a cutting edge of the provided cutting die; and generate an image of a modified desired cutting die based on the offset distance; and at least one bending machine operable to provide the provided cutting die based on the generated image of the modified desired cutting die.

In at least one embodiment, the processor is operable to, when generating the image of the modified desired cutting die, apply the offset distance to the cutting edge of the desired cutting die such that the shape of the modified desired cutting die is smaller than the shape of the desired cutting die.

In at least one embodiment, the processor is operable to, when generating the image of the modified desired cutting die, modify a position of the one or more features of the cutting edge of the desired cutting die based on the desired tolerance.

In at least one embodiment, the processor is operable to, when generating the image of the modified desired cutting die, modify a position of the one or more features of the cutting edge of the desired cutting die based on the offset distance.

In at least one embodiment, the processor is operable to, when generating the image of a modified desired cutting die, modify a feature of the cutting edge of the desired cutting die based on one or more of the offset distance and the desired tolerance.

In at least one embodiment, the offset distance is less than the desired tolerance.

In at least one embodiment, the offset distance is less than about 75% of the desired tolerance, or less than about 60% of the desired tolerance, or about 50% of the desired tolerance.

In at least one embodiment, the offset distance is greater than the desired tolerance.

According to another broad aspect, a method of providing a cutting die is described herein. The method includes receiving at least one image of a desired cutting die; identifying an entire cutting edge of the desired cutting die as shown in the least one image of the desired cutting die, the cutting edge being positioned around a perimeter of the cutting die; identifying at least one feature of the cutting edge of the desired cutting die as shown in the least one image of the desired cutting die; retrieving a set of cutting edge specifications from the data storage device, the set of cutting edge specifications including a desired tolerance for differences between a shape of the desired cutting die and a shape of a provided cutting die; based the on the desired tolerance, calculating an offset distance between the cutting edge of the desired cutting die and a cutting edge of the provided cutting die; generating an image of a modified desired cutting die based on the offset distance; and providing the provided cutting die based on the generated image of the modified desired cutting die.

In at least one embodiment, generating the image of the modified desired cutting die includes applying the offset distance to the cutting edge of the desired cutting die such that the shape of the modified desired cutting die is smaller than the shape of the desired cutting die.

In at least one embodiment, generating the image of the modified desired cutting die includes modifying a position of the one or more features of the cutting edge of the desired cutting die based on the desired tolerance.

In at least one embodiment, generating the image of the modified desired cutting die includes modifying a position of the one or more features of the cutting edge of the desired cutting die based on the offset distance.

In at least one embodiment, generating the image of a modified desired cutting die includes modifying a feature of the cutting edge of the desired cutting die based on one or more of the offset distance and the desired tolerance.

In at least one embodiment, the offset distance is less than the desired tolerance.

In at least one embodiment, the offset distance is less than about 75% of the desired tolerance, or less than about 60% of the desired tolerance, or about 50% of the desired tolerance.

In at least one embodiment, the offset distance is greater than the desired tolerance.

According to another broad aspect, a method of providing an image of a modified desired cutting die is described herein. The method includes receiving at least one image of a desired cutting die; identifying an entire cutting edge of the desired cutting die as shown in the least one image of the desired cutting die, the cutting edge being positioned around a perimeter of the cutting die; identifying at least one feature of the cutting edge of the desired cutting die as shown in the least one image of the desired cutting die; retrieving a set of cutting edge specifications from the data storage device, the set of cutting edge specifications including a desired tolerance for differences between a shape of the desired cutting die and a shape of a provided cutting die; based the on the desired tolerance, calculating an offset distance between the cutting edge of the desired cutting die and a cutting edge of the provided cutting die; and generating an image of a modified desired cutting die based on the offset distance.

In at least one embodiment, generating the image of the modified desired cutting die includes applying the offset distance to the cutting edge of the desired cutting die such that the shape of the modified desired cutting die is smaller than the shape of the desired cutting die.

In at least one embodiment, generating the image of the modified desired cutting die includes modifying a position of the one or more features of the cutting edge of the desired cutting die based on the desired tolerance.

In at least one embodiment, generating the image of the modified desired cutting die includes modifying a position of the one or more features of the cutting edge of the desired cutting die based on the offset distance.

In at least one embodiment, generating the image of a modified desired cutting die includes modifying a feature of the cutting edge of the desired cutting die based on one or more of the offset distance and the desired tolerance.

In at least one embodiment, the offset distance is less than the desired tolerance.

In at least one embodiment, the offset distance is less than about 75% of the desired tolerance, or less than about 60% of the desired tolerance, or about 50% of the desired tolerance.

In at least one embodiment, the offset distance is greater than the desired tolerance.

According to another broad aspect, a method of reducing spacing between cutting dies arranged on a die board is described herein. The method includes receiving a plurality of images of desired cutting dies; generating an image of a modified desired cutting die for each of the images of desired cutting dies, each modified desired cutting die having a cutting edge being offset inwardly relative to a cutting edge of the desired cutting die by a calculated offset distance, the calculated offset distance based on a desired tolerance for differences between a shape of the desired cutting die and a shape of a provided cutting die; providing, using a bending machine, the modified desired cutting dies based on the generated images of the modified desired cutting dies; and arranging the modified desired cutting dies on the die board such that a spacing between each of the modified desired cutting dies is less than or equal to the desired tolerance for differences between a shape of the desired cutting die and a shape of a provided cutting die.

### BRIEF DESCRIPTION OF THE DRAWINGS

The drawings included herewith are for illustrating various examples of articles, methods, and apparatuses of the present specification and are not intended to limit the scope of what is taught in any way. In the drawings:

FIG. 1 is a block diagram of a system for providing a die, according to at least one embodiment described herein.

FIG. 2 is a top down view of a digital representation of desired cutting die, according to at least one embodiment described herein.

FIG. 3 is a top down view of a portion of an image including both a desired cutting die and modified desired cutting die, according to at least one embodiment described herein.

FIG. 4 is a flow diagram of a method of generating an image of a modified cutting die, according to at least one embodiment described herein.

FIG. 5A is an image of an exemplary user interface showing a feature of the modified desired cutting die that the processor is operable to modify, according to at least one embodiment described herein.

FIG. 5B is a portion of an image including both a desired cutting die and modified desired cutting die showing the feature of the modified desired cutting die that the processor is operable to modify via the user interface of FIG. 5A.

FIG. 6A is an image of an exemplary user interface showing a feature of the modified desired cutting die that the processor is operable to modify, according to at least one embodiment described herein.

FIG. 6B is a portion of an image including both a desired cutting die and modified desired cutting die showing the feature of the modified desired cutting die that the processor is operable to modify via the user interface of FIG. 6A.

FIG. 7A is an image of an exemplary user interface showing a feature of the modified desired cutting die that the processor is operable to modify, according to at least one embodiment described herein.

FIG. 7B is a portion of an image including both a desired cutting die and modified desired cutting die showing the feature of the modified desired cutting die that the processor is operable to modify via the user interface of FIG. 7A.

FIG. 8A is an image of an exemplary user interface showing a feature of the modified desired cutting die that the processor is operable to modify, according to at least one embodiment described herein.

FIG. 8B is a portion of an image including both a desired cutting die and modified desired cutting die showing the feature of the modified desired cutting die that the processor is operable to modify via the user interface of FIG. 8A.

FIG. 9A is an image of an exemplary user interface showing a feature of the modified desired cutting die that the processor is operable to modify, according to at least one embodiment described herein.

FIG. 9B is a portion of an image including both a desired cutting die and modified desired cutting die showing the feature of the modified desired cutting die that the processor is operable to modify via the user interface of FIG. 9A.

FIG. 10A is an image of an exemplary user interface showing a feature of the modified desired cutting die that the processor is operable to modify, according to at least one embodiment described herein.

FIG. 10B is a portion of an image including both a desired cutting die and modified desired cutting die showing the feature of the modified desired cutting die that the processor is operable to modify via the user interface of FIG. 10A.

FIG. 11A is an image of an exemplary user interface showing a feature of the modified desired cutting die that the processor is operable to modify, according to at least one embodiment described herein.

FIG. 11B is a portion of an image including both a desired cutting die and modified desired cutting die showing the feature of the modified desired cutting die that the processor is operable to modify via the user interface of FIG. 11A.

FIG. 12A is an image of an exemplary user interface showing a feature of the modified desired cutting die that the processor is operable to modify, according to at least one embodiment described herein.

FIG. 12B is a portion of an image including both a desired cutting die and modified desired cutting die showing the feature of the modified desired cutting die that the processor is operable to modify via the user interface of FIG. 12A.

FIG. 13A is an image of an exemplary user interface showing a feature of the modified desired cutting die that the processor is operable to modify, according to at least one embodiment described herein.

FIG. 13B is a portion of an image including both a desired cutting die and modified desired cutting die showing the feature of the modified desired cutting die that the processor is operable to modify via the user interface of FIG. 13A.

FIG. 14 is a flow diagram of a method of providing a cutting die, according to at least one embodiment described herein.

FIG. 15 is a top down view of a plurality of provided cutting dies, according to at least one embodiment described herein.

FIG. 16 is another top down view of a plurality of provided cutting dies, according to at least one embodiment described herein.

FIG. 17 is another top down view of a plurality of provided cutting dies, according to at least one embodiment described herein.

### DETAILED DESCRIPTION

Various systems and/or methods will be described below to provide an example of an embodiment of each claimed invention. No embodiment described below limits any claimed invention and any claimed invention may cover systems and/or methods that differ from those described below. The claimed inventions are not limited to systems and/or methods having all of the features of any one system and/or method described below or to features common to multiple or all of the systems and/or methods described below. It is possible that a system and/or method described below is not an embodiment of any claimed invention. Any invention disclosed in systems and/or methods described below that is not claimed in this document may be the subject matter of another protective instrument, for example, a continuing patent application, and the applicants, inventors or owners do not intend to abandon, disclaim, or dedicate to the public any such invention by its disclosure in this document.

As used herein and in the claims, two or more parts are said to be “coupled”, “connected”, “attached”, “joined”, “affixed”, or “fastened” where the parts are joined or operate together either directly or indirectly (i.e., through one or more intermediate parts), so long as a link occurs. As used herein and in the claims, two or more parts are said to be “directly coupled”, “directly connected”, “directly attached”, “directly joined”, “directly affixed”, or “directly fastened” where the parts are connected in physical contact with each other. As used herein, two or more parts are said to be “rigidly coupled”, “rigidly connected”, “rigidly attached”, “rigidly joined”, “rigidly affixed”, or “rigidly fastened” where the parts are coupled so as to move as one while maintaining a constant orientation relative to each other. None of the terms “coupled”, “connected”, “attached”, “joined”, “affixed”, and “fastened” distinguish the manner in which two or more parts are joined together.

Further, although method steps may be described (in the disclosure and/or in the claims) in a sequential order, such methods may be configured to work in alternate orders. In other words, any sequence or order of steps that may be described does not necessarily indicate a requirement that the steps be performed in that order. The steps of methods described herein may be performed in any order that is practical. Further, some steps may be performed simultaneously.

Furthermore, it will be appreciated that for simplicity and clarity of illustration, where considered appropriate, reference numerals may be repeated among the figures to indicate corresponding or analogous elements. In addition, numerous specific details are set forth in order to provide a thorough understanding of the example embodiments described herein. However, it will be understood by those of ordinary skill in the art that the examples described herein may be practiced without these specific details. In other instances, well-known methods, procedures, and components have not been described in detail so as not to obscure the examples described herein.

As used herein, the wording “and/or” is intended to represent an inclusive-or. That is, “X and/or Y” is intended to mean X or Y or both, for example. As a further example, “X, Y, and/or Z” is intended to mean X or Y or Z or any combination thereof.

Leather and/or other fabric products may be made from pieces that have been cut according to one or more patterns. To cut the pieces of leather or fabric, dies may be made in the shapes of the patterns, placed on large pieces of the leather or fabric (e.g. a leather hide) and pushed through the leather or fabric in a press. Several different die shapes may be needed to cut all the distinct pieces that are sewn together to create the end product. And any given number of end products will require a certain number of pieces cut according to each pattern.

To minimize time and maximize efficiency, several dies are typically arranged on a hide or large piece of fabric to be cut simultaneously. The arrangement of the dies on the hide or fabric can be optimized to maximize the usage of acceptable leather or fabric and minimize unusable material of the hide between adjacent dies, also known as scrap. Typically, to minimize scrap while maintaining dimensional consistency of pieces of leather or fabric cut at the same time, designers define an acceptable tolerance for variations in size and shape of each individual cutting die. Acceptable tolerances may vary anywhere from 1 millimeter (mm) to 10 mm, depending on the fabric type, size of the end product, shape of the piece, etc. that the die is used to cut.

With the advent of improved systems and methods of manufacturing cutting dies to increasingly precise size and shape specifications, there is an opportunity to reduce the spacing between adjacent dies in a die press and cut pieces of leather or fabric to sizes and/or shapes that are within a smaller tolerance than requested by the manufacturer of the end product. Reducing the spacing between adjacent dies in a die press can reduce the amount of scrap fabric or scrap leather created during a cutting process, which can save money and increase efficiency. For example, in some examples, a manufacturer's requested tolerance may be in the range of about 5 mm or less, or 3 mm or less, or 2 mm, or less than 2 mm. Cutting a piece of leather or fabric to a shape that is within a tolerance that is 1-2 mm narrower than a manufacturer's requested tolerance, when considered over a length of a typical die board (e.g. about 6 meters), can save up to 20 or 30 mm of material.

Ensuring that the shape of a manufactured cutting die, and the leather and/or fabric cut using the manufactured cutting die, falls within a tolerance that is narrower than a manufacturer's requested tolerance can be difficult. It requires modifying a manufacturer's requested size and shape of a cutting die to make it smaller while adjusting the position of one or more features of the die to maintain the geometric relationship between the features to ensure that pieces of leather and/or fabric cut using the adjusted die still fit within the pattern of pieces that are stitched together to form the desired end product.

The systems and methods herein provide for modifying a manufacturer's requested size and shape of a cutting die to reduce the size and shape while maintaining the geometric relationship between the features of the cutting die. The systems and methods described herein also provide for arranging a plurality of cutting dies on a die press to reduce an effective amount of material used when the plurality of cutting dies are nested together to cut a single piece of material into a plurality of shapes.

It should be noted that although the example embodiments described herein are described with regard to cutting dies, for example cutting dies for use in cutting fabric, automobile components, composites, plastics, or other materials, it should be understood that the methods and systems described herein may be applied to other industries and processes where the size of geometric shapes (e.g. a position of a boundary of the geometric shapes) needs to be modified or repositioned while maintaining a specific geometric relationship between aspects or features or portions of the geometric shape. In at least one embodiment, the methods and systems described herein may be useful in other industries and processes where a footprint (i.e. an area occupied by) of a geometric shape needs to be reduced while maintaining a specific positional relationship between aspects or features or portions of the geometric shape.

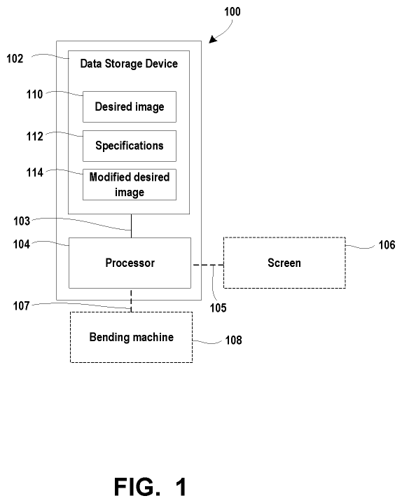

Turning to the figures, and referring to FIG. 1, illustrated therein is a system 100 for providing a cutting die, according to at least one embodiment described herein.

System 100 includes at least one data storage device 102 communicatively coupled by a communication link 103 to at least one processor 104. The data storage device 102 stores at least an image 110 of a desired cutting die, a set of cutting edge specifications 112, and an image 114 of a modified desired cutting die.

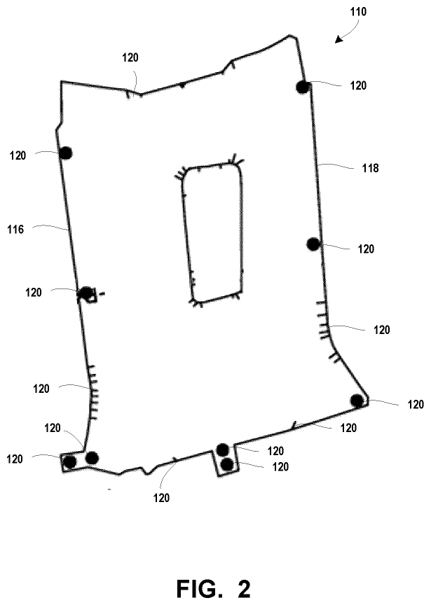

The image 110 includes a digital representation (e.g. as a .DXF file, a CAD file, or the like, containing a single cavity or a plurality of cavities) of at least one desired cutting die 116 (i.e. a model of a cutting die that is to be manufactured). FIG. 2 shows an exemplary image 110 of a digital representation of desired cutting die 116 showing a desired shape of the desired cutting die 116. Desired cutting die 116 of the image 110 includes a cutting edge 118. Cutting edge 118 is a sharpened, upper portion of the cutting die 116 and is present on at least a portion of a perimeter of the desired cutting die 116. In at least one embodiment, the cutting edge 118 is present on the entire perimeter of the desired cutting die 116. Desired cutting die 116 and/or cutting edge 118 may have various shapes and may include sharp bends and/or one or more other features 120. For example, the desired cutting die of image 110 may include a sharp bend or an angle (e.g. two portions joined at a 30 degree angle, a 45 degree angle or a 90 degree angle, or the like). Features 120 may also include but are not limited to slits, notches, corners, blades, or the like. In at least one embodiment, the desired cutting die may also include bracing (not shown). Further still, braces and faceplates of the dies may be adjusted or their positions within a die may be changed to accommodate dies having an edge shape designed to a smaller dimensional tolerance.

The set of cutting edge specifications 112 include, for example, a tolerance for a difference between a shape of the desired cutting die and a shape of a provided cutting die. It should be noted that the term “tolerance” as used herein refers to a pre-selected distance between a maximum dimensional boundary and a minimum dimensional boundary of the provided cutting die relative to the desired cutting die. For instance, without limiting the foregoing, the tolerance may be about 5 mm, or about 3 mm, or about 2 mm, meaning that the shape of the provided cutting die must fall within a 5, or 3, or 2, or less mm spacing (e.g. 1 mm in a direction that increases the shape of the desired cutting die and 1 mm in a direction that decreases the shape of the desired cutting die) around the perimeter of the desired cutting die to be acceptable. In at least one embodiment, the set of cutting edge specifications 112 is a digital file or a portion of a digital file.

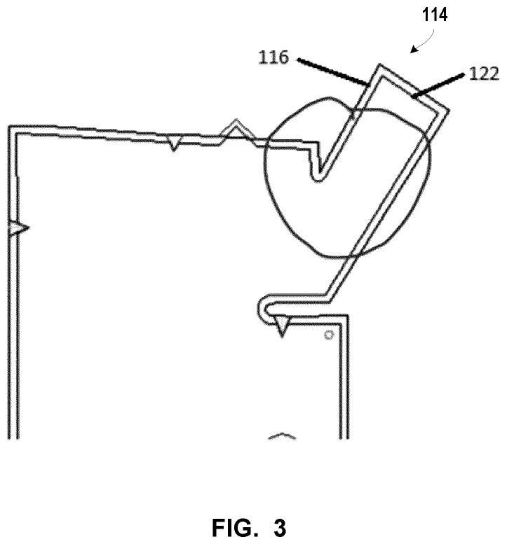

The image 114 includes a digital representation (e.g. as a .DXF file, a CAD file, or the like) of a modified desired cutting die 122. The modified desired cutting die 122 has undergone a modification, such as but not limited to a change in shape, relative to the desired cutting die 116 resulting from one or more of the methods described below. In at least one embodiment described herein, the modified desired cutting die 122 is smaller (i.e. has a smaller area) that the desired cutting die 116. In at least one embodiment, the modified desired cutting die 122 is larger (i.e. has a larger area) that the desired cutting die 116. In at least one embodiment, image 114 also includes a digital representation of the desired cutting die 116. FIG. 3 shows a portion of an image 114 including both desired cutting die 116 and modified desired cutting die 122.

The system 100 also includes at least one processor 104. The processor 104 is communicatively coupled to the data storage device 102, e.g. such that the processor 104 may retrieve one or more of the image 110 of a desired cutting die, the set of cutting edge specifications 112, and the image 114 of a modified desired cutting die that are stored on the data storage device 102.

The processor 104 may be communicatively coupled to the data storage device 102 by a first communications link 103, which may be wired (as illustrated in FIG. 1) and/or wireless (e.g. through the Internet or an intranet or the like).

The processor 104 is operable to modify the image 110 of a desired cutting die 116, as described further below. The processor 104 is operable to generate the image 114 of the modified desired cutting die 122, optionally including the desired cutting die 116, as also described further below.

In at least one embodiment, system 100 may also include an electronic screen 106 (e.g. a touchscreen), and the processor 104 may be operable to present information via the screen 106. The processor may be communicatively coupled to the screen 106 by an optional communications link 105, which may also be wired (as illustrated) and/or wireless.

In at least one embodiment, system 100 may also include a bending machine 108 (e.g. a touchscreen) operable to provide the cutting die. In at least one embodiment, the processor 104 may be operable to present the generated image 114 of the modified desired cutting die 122, and/or any technical details of the modified desired cutting die 122, including but not limited to any information contained within the set of cutting edge specifications 112, to the bending machine 108. The processor may be communicatively coupled to the bending machine 108 by an optional communications link 107, which may also be wired (as illustrated) and/or wireless.

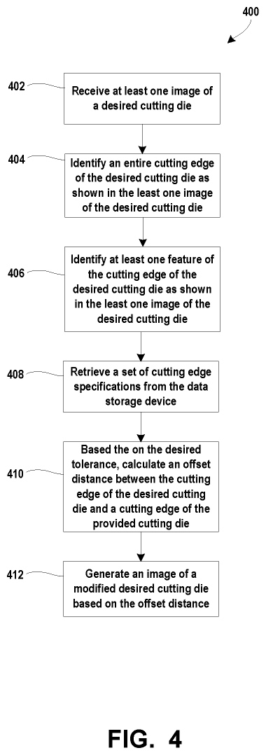

Referring to FIG. 4, a method 400 of generating an image of a modified cutting die is described herein. During method 400, processor 104 is operable to modify the image 110 of a desired cutting die 116 and generate the image 114 of the modified desired cutting die 122, optionally including the desired cutting die 116, as further described below.

The processor 104 is configured to, at step 402, receive the at least one image 110 of the desired cutting die 116. The processor 104 may retrieve the at least one image from the data storage device 102, however in some examples, the processor 104 may optionally receive the at least one image 110 of the desired cutting die 116 directly from another optional component of the system 100, such as but not limited a different storage device or from a mail client.

In some examples, the at least one image 110 is a plurality of images. For example, the at least one image 110 may be a set of at least 4 images, at least 6 images, or at least 9 images.

At step 404, the processor 104 identifies the entire cutting edge 118 of the desired cutting die 116 shown in the at least one image 110. For example, the processor 104 may include software that may identify the perimeter of the cutting die 116 shown in the at least one image 110. In at least one embodiment, the software algorithm is configured to detect the perimeter of the cutting die 116 shown in the at least one image 110 when the perimeter is represented by a solid line. Where the at least one image 110 is a plurality of images, the processor 104 may find the edge lines for each cutting edge of each of the plurality of images and filter out outlier data (e.g. outlier data that affect the ability to find consistent edges).

In at least one embodiment, the at least one image 110 of the cutting edge die 116 is a CAD or CAM file and the data processed for identifying the cutting edge is vector data and the image shown is the vector data rasterized to create a visual representation to the user. In some cases, the CAD data does not form a closed shape. In these cases, the systems described herein include specifications and routines to locate the end point for a nearby entity, and if within a predefined amount, assume that is the next entity in the shape and continue to loop through the entire vector data until there is a closed entity.

At step 406, the processor identifies at least one feature 120 of the cutting edge 118 of the desired cutting die 116. For example, the processor 104 may include software that may identify features 120 based on the shape of indications (e.g. black markings) present on or adjacent to the perimeter of the cutting die 116.

The processor 104 is also configured to, at step 408, retrieve the set of cutting edge specifications 112, e.g. from the data storage device 102. As noted above, the set of cutting edge specifications 112 may include, for example, a tolerance for differences between a shape of the provided cutting die and a shape of the desired cutting die 116. The set of cutting edge specifications 112 may also include other information relevant to generating image 114 of a modified desired cutting die 122. The processor 104 may retrieve all these specifications or only the specifications for the cutting die 116 shown in the at least one image 110.

At step 410, the processor calculates an offset distance between the cutting edge 118 of the desired cutting die 116 and a cutting edge of a provided cutting die. The calculation of the offset distance between the cutting edge 118 of the desired cutting die 116 and the cutting edge of the provided cutting die is based on the tolerance for differences between a shape of the provided cutting die and the shape of the desired cutting die 116. In at least one embodiment, the offset distance is less than the tolerance for differences between a shape of the provided cutting die and a shape of the desired cutting die 116. In at least one embodiment, the offset distance is less than about 75% of the desired tolerance, or less than about 60% of the desired tolerance, or about 50% of the desired tolerance. For example, if the tolerance is 2 mm the offset distance may be 1 mm.

In at least one embodiment, the offset distance is greater than the desired tolerance.

At step 412 the processor is operable to generating the image of the modified desired cutting die 122. When generating the image of the modified desired cutting die 122, the modified desired cutting die is based on the offset distance calculated in step 410.

In at least one embodiment, when generating the image of the modified desired cutting die, the processor is operable to apply the offset distance to the cutting edge of the desired cutting die such that the shape of the modified desired cutting die is smaller than the shape of the desired cutting die.

In at least one embodiment, when generating the image of the modified desired cutting die, the processor is operable to modify a position of the one or more features 120 of the cutting edge 118 of the desired cutting die 116 based on the desired tolerance.

In at least one embodiment, when generating the image of the modified desired cutting die, the processor is operable to modify a position of the one or more features 120 of the cutting edge 118 of the desired cutting die 116 based on the offset distance.

In at least one embodiment, when generating the image of the modified desired cutting die, the processor is operable to modify one or more features 120 of the cutting edge 118 of the desired cutting die 116 based on one or more of the offset distance and the desired tolerance.

In addition to the perimeter of the die itself, other features that may require offset calculations include but are not limited to corners, slits, blades, and notches. In at least one embodiment, there may also be the need to adjust other features such as perforating punches and cutouts located internal to the perimeter of the cavity. This would need to be assessed based on the internal feature's proximity to the perimeter. Features located close to the perimeter are likely to need offsetting whereas features located further inward can likely stay in their original positions.

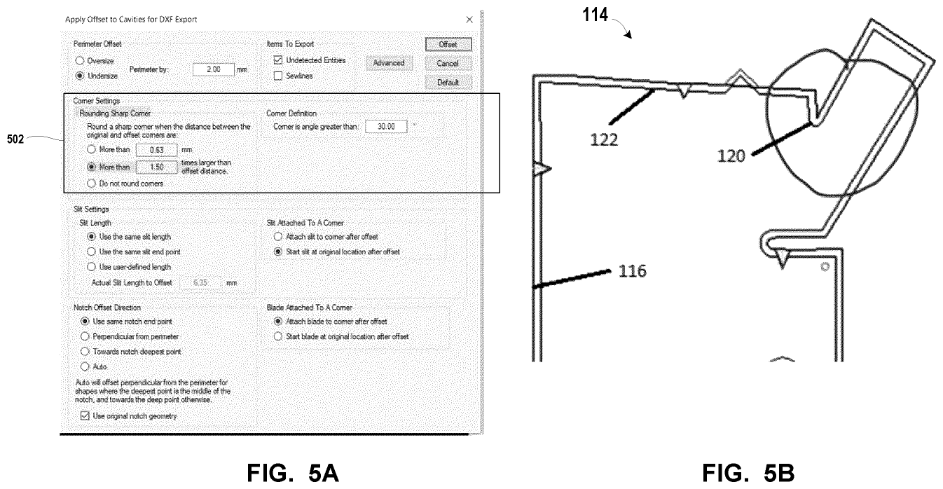

At FIG. 5A, illustrated therein is an exemplary user interface showing one example of a feature of the modified desired cutting die 122 that the processor is operable to modify. Here, feature 120, is a corner, or a sharp corner, of the cutting die shown in the image 114 of FIG. 5B. A corner refers to any angle within a die greater than a right angle forming an acute angle. An acute angle when offset will have the intersection of the two sides extend further into the inside of the cavity and possibly past the allowable seam allowance of the part. Because of this it is necessary to radius the tip of the offsets in order to prevent this from occurring.

In at least one embodiment, as shown in box 502, the processor is operable to round a corner, or round a sharp corner, as is present in the image 110 of the desired cutting die 116 after generating the image 114 of the modified desired cutting die 122. In FIG. 5B, feature 120 is shown as a sharp corner. After generating the image 114 of the modified desired cutting die 122, applying the calculated offset of step 410 may result in at least a portion of the corner 120 of the offset of modified desired cutting die 122 being positioned beyond the desired tolerance for differences between the shape of the desired cutting die 116 and the shape of a provided cutting die. Accordingly, in at least one embodiment, the processor is operable to round a corner of the modified desired cutting die 122 to maintain the corner 120 being within the desired tolerance.

In at least one embodiment, as shown in box 502, the processor is operable to round a corner when the distance between the original and the offset corner of the modified desired cutting die 122 is greater than a preselected distance (e.g. 0.63 mm, as shown in FIG. 5A). In at least one embodiment, as shown in box 502, the processor is operable to round a corner when the distance between the original and the offset corner of the modified desired cutting die 122 is greater than a preselected multiple of the offset distance (e.g. 1.50 times the offset distance, as shown in FIG. 5A).

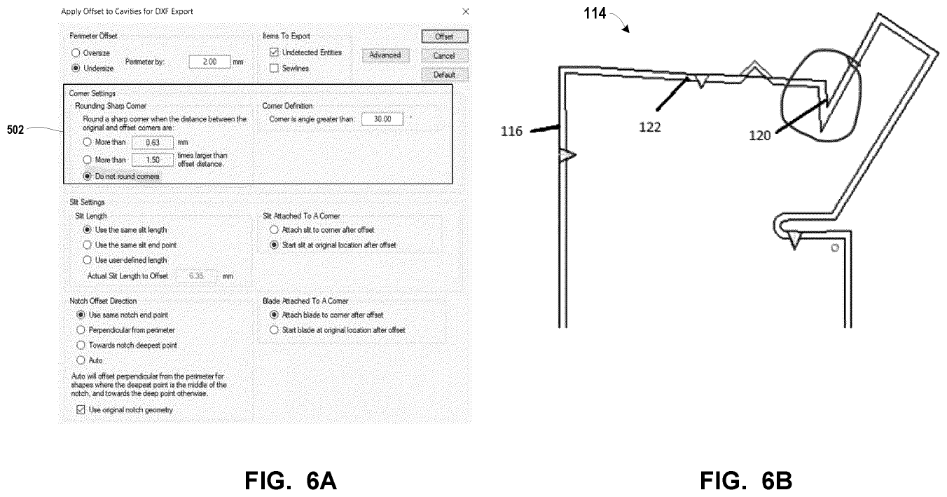

In at least one embodiment, as shown in box 502, the processor is operable to not round a corner of the modified desired cutting die 122 after generating the image 114 of the modified desired cutting die 122. An example of this is shown in FIGS. 6A and 6B.

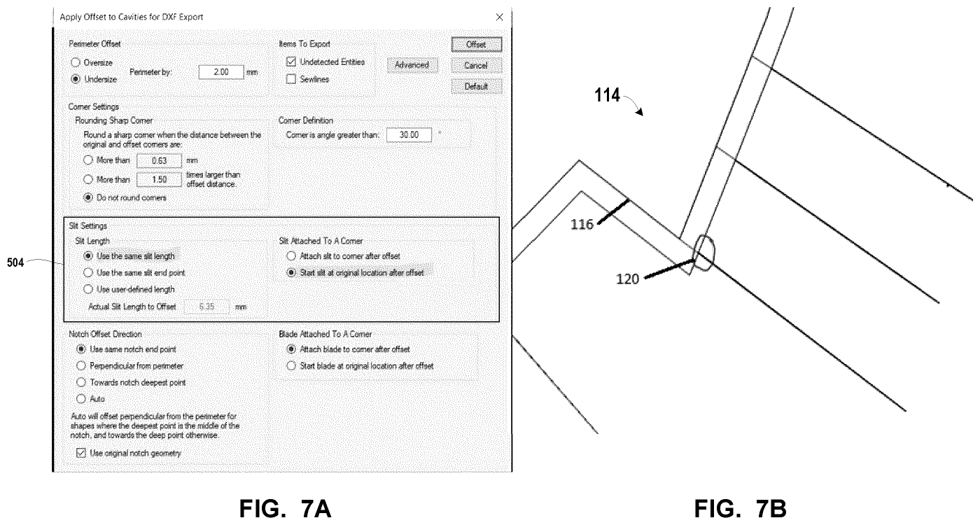

At FIG. 7A, illustrated therein is an exemplary user interface showing another example of a feature of the modified desired cutting die 122 that the processor is operable to modify. Here, feature 120 is a slit in the cutting die shown in the image 114 of FIG. 7B. A slit refers to a small section, usually between 2 and 25 mm of die steel similar to the perimeter steel of the die but joined (e.g. welded) perpendicularly to either the inside or outside of the perimeter of the die. A slit is required to allow the material to fold during the sewing process without the material buckling.

In at least one embodiment, as shown in box 504 of FIG. 7A, the processor is operable to use a same slit length as is present in feature 120 of desired cutting die 116 after generating the image 114 of the modified desired cutting die 122.

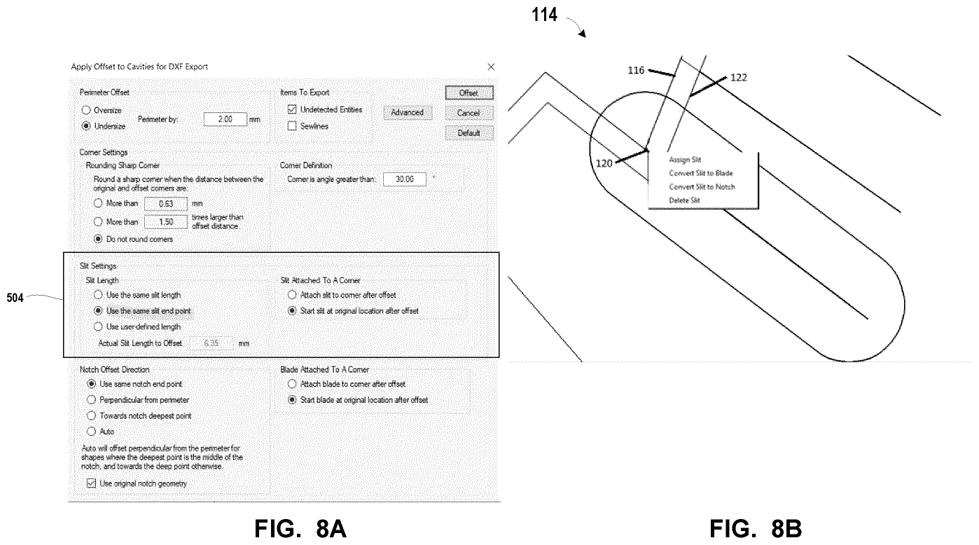

In at least one embodiment, as shown in box 504 of FIG. 8A, the processor is operable to use a same slit end point as is present in feature 120 of desired cutting die 116 after generating the image 114 of the modified desired cutting die 122 (see FIG. 8B).

In at least one embodiment, the processor is operable to modify a length of a slit present in feature 120 of desired cutting die 116 after generating the image 114 of the modified desired cutting die 122. For instance, the processor may be operable to modify the length of a slit present in the desired cutting die 116 to a user defined or a user selected length after generating the image 114 of the modified desired cutting die 122.

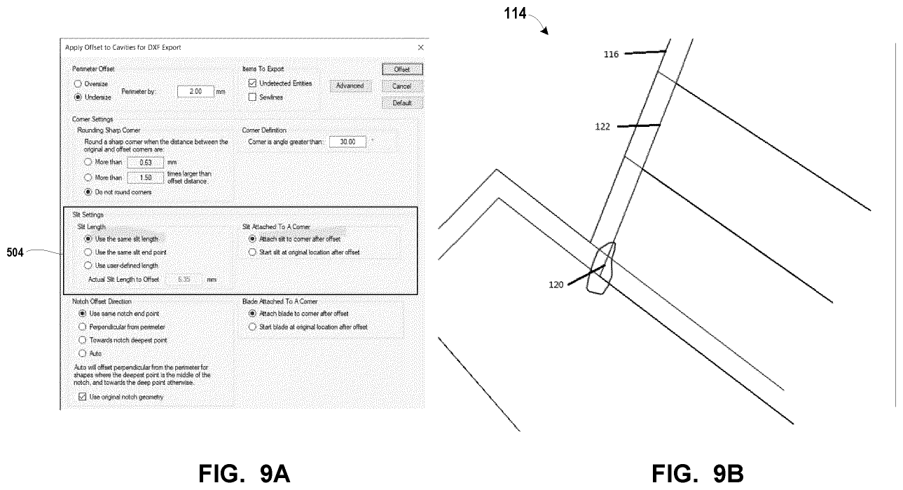

In at least one embodiment, as shown in box 504 of FIG. 9A, the processor is operable to modify a position of the slit after generating the image 114 of the modified desired cutting die 122. For instance, the processor may be operable to attach the slit to a corner after generating the image 114 of the modified desired cutting die 122. In at least one embodiment, the processor is operable to maintain a position of a slit after generating the image 114 of the modified desired cutting die 122 (see FIG. 9B). For instance, the processor may be operable to start the slit at an original location (e.g. a location of the cutting edge as in the desired cutting die 116) after generating the image 114 of the modified desired cutting die 116.

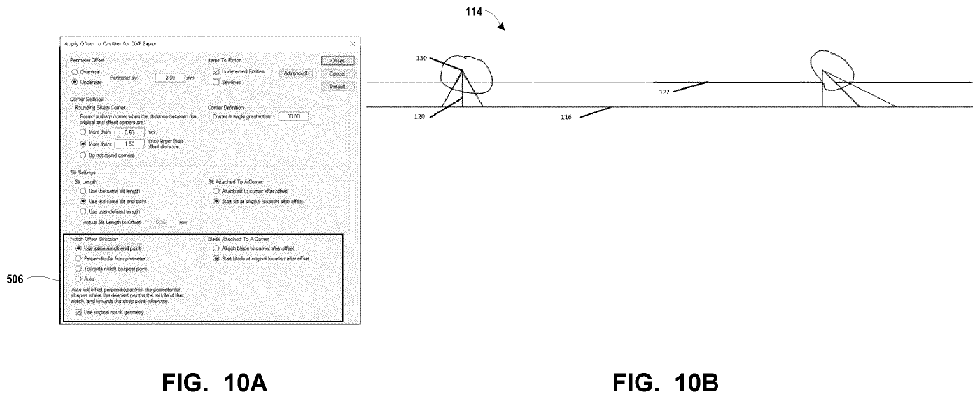

At FIG. 10A, illustrated therein is an exemplary user interface showing another example of a feature of the modified desired cutting die 122 that the processor is operable to modify. Here, feature 120 is a notch in the cutting die shown in the image 114 of FIG. 10B. A notch refers to a small feature formed into the cutting edge of the steel that cannot be formed with typical bending tools and requires a set of matched male and female forming tools. In order to achieve the desired accuracy and definition, the steel is heated during the forming operation. A nick (as referred to as a “top notch”) is formed into the upper portion of the cutting edge. A “full-body notch” is similar to a nick and formed with male/female tooling, however, runs the entire height of the die steel. These features are typically in the shape of a V, U or |_|, where both width and depth can be made to suit the customer's requirements. These features may also be trapezoidal or ½ V notch.

Nicks and/or notches may be used as a visual sewing aid to keep two mating parts in alignment during the sewing operation. Nicks and/or notches may be placed equally around two mating parts and, during the sewing operation, the operator is required to keep these aligned, doing so ensures that at the end of the sewing operation the two ends meet.

Both nicks and/or notches and/or slits are used to relieve stresses in the finished part when folded during the sewing operation and to prevent wrinkles in the finished part. Typically, nicks are used to relieve concave sections relative to the finished part and slits are used to relieve stresses in convex sections relative to the finished part.

In at least one embodiment, as shown in box 506 of FIG. 10A, the processor may be operable to modify the dimensions of a notch in the cutting edge of the modified desired cutting die 122 after generating the image 114 of the modified desired cutting die 122. As shown in FIG. 10B, after generating the image 114 of the modified desired cutting die 122, applying the calculated offset of step 410 may result in dimensions (e.g. size and shape) of the notch 120 of modified desired cutting die 122 being different than dimensions of the notch 120 of the desired cutting die 116. Accordingly, in at least one embodiment, the processor is operable to adjust dimensions of the notch 120 of modified desired cutting die 122 after generating the image 114 of the modified desired cutting die 122.

For instance, in at least one embodiment, as shown in box 506 of FIG. 10A, the processor is operable to use a same notch end point 130 as is present in feature 120 of desired cutting die 116 after generating the image 114 of the modified desired cutting die 122 (see FIG. 10B).

In at least one embodiment, the processor is operable to change the notch offset direction so that it is perpendicular from a perimeter of the cutting edge of the modified desired cutting die 122 after generating the image 114 of the modified desired cutting die 122.

In at least one embodiment, the processor is operable to change the notch offset direction so that it is towards the notch deepest point of the cutting edge of the modified desired cutting die 122 after generating the image 114 of the modified desired cutting die 122.

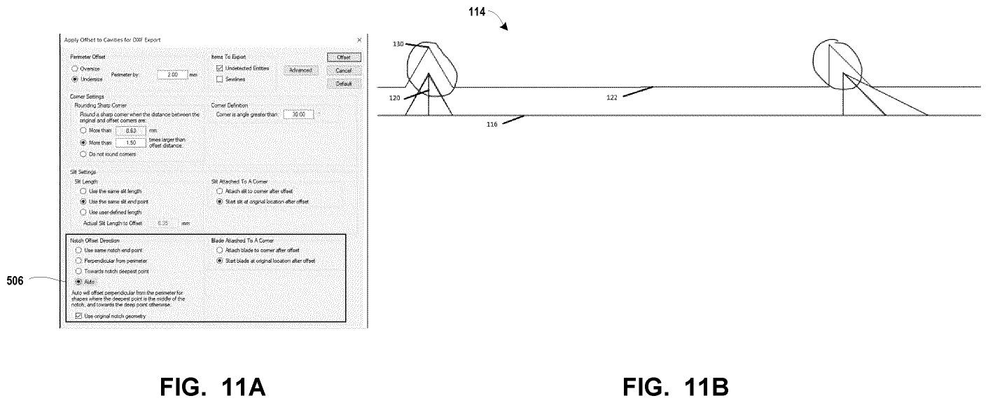

In at least one embodiment, as shown in box 506 of FIG. 11A, the processor is operable to automatically change the dimension of the notch 120 so that the notch 120 is offset perpendicular from the perimeter for shapes where the deepest point of the notch is in the middle of the notch, and towards the deep point otherwise after generating the image 114 of the modified desired cutting die 122. In at least one embodiment, a user of the interface may select if the processor uses the original notch geometry or not after the processor generates the image 114 of the modified desired cutting die 122 (see FIG. 11B).

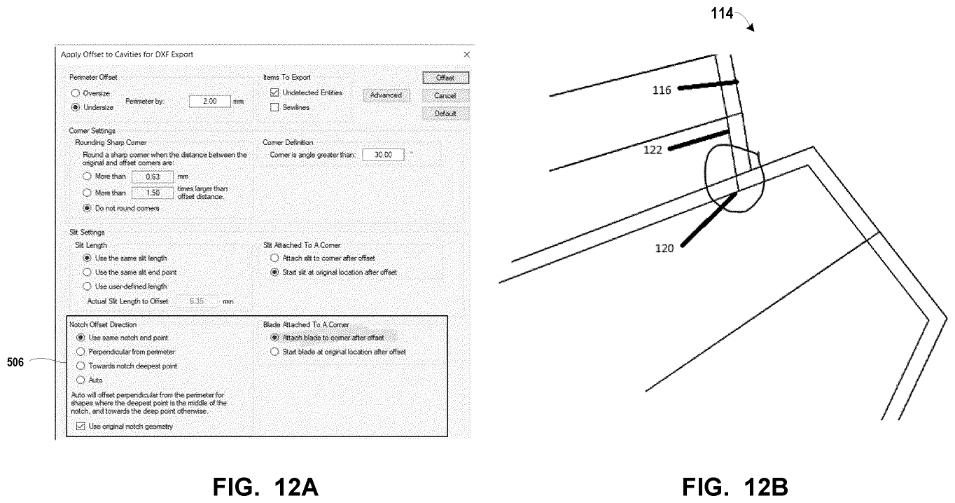

In at least one embodiment, as shown in box 506 of FIG. 12A, the processor may be operable to modify a position of a blade of the notch 120. As shown in FIG. 12B, after generating the image 114 of the modified desired cutting die 122, the processor may be operable to attach a blade to a corner after applying the offset. Specifically, the anchor point of the blade moves to the new position based on offsets to the perimeter and the blade remains the original length.

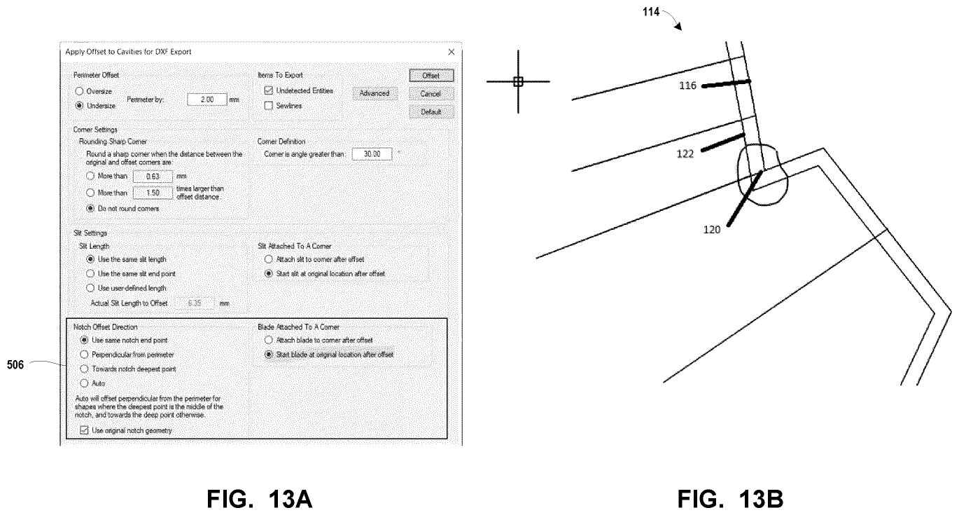

In at least one embodiment, as shown in box 506 of FIG. 13A, the processor may be operable to modify a position of a blade of the notch 120. As shown in FIG. 13B, after generating the image 114 of the modified desired cutting die 122, the processor may be operable to start the blade at its original location after applying the offset. Specifically, here, the blade retains the original anchor point, the perimeter is offset, and the result is a blade which is shorter in overall length an amount roughly equal to the offset, that is depending on the angle the blade is attached to the corner.

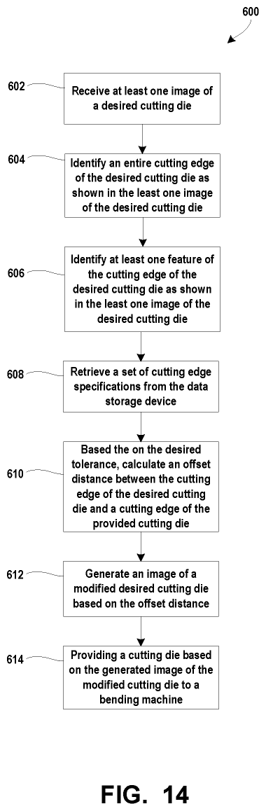

Referring now to FIG. 14, illustrated is a method 600 of providing a cutting die, as described herein.

Method 600 includes steps 602-612 corresponding to steps 402-412 in the method 400 of generating an image of a modified cutting die. Following step 612, method 600 includes a step 614 of providing a cutting die based on the generated image 122 of the modified desired cutting die. In this step, processor 104 is operable to transmit the generated image 122 of the modified desired cutting die to a bending machine 108 and the bending machine 108 is operable to provide the cutting die.

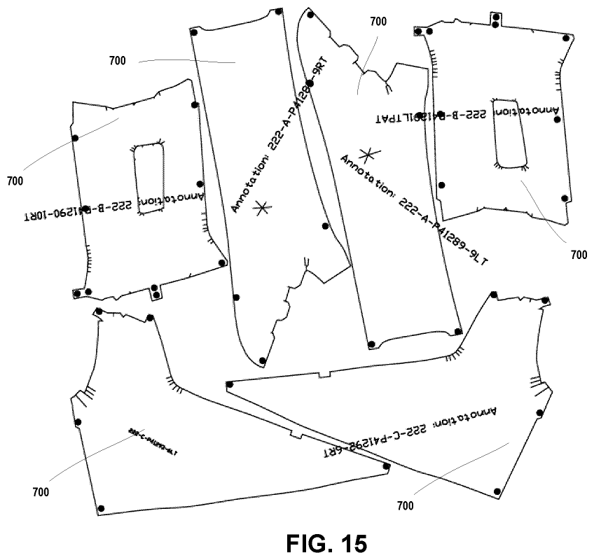

Referring now to FIGS. 15 to 17, the methods 400 and 600 described herein may be used to provide a cutting die, such as but not limited to the provided cutting dies 700 shown therein. Each of the provided cutting dies 700 shown therein has a smaller footprint (i.e. the area occupied by the provided cutting die) than a footprint of a respective desired cutting die because, as noted above, the methods included herein provide for the modifying the cutting edge of the desired cutting die within a tolerance. Accordingly, the arranging a plurality of provided cutting dies 700, for example on a cutting board, results in a total footprint of the plurality of provided cutting dies 700 being smaller than a total footprint of the plurality of respective desired cutting dies. The smaller total footprint of the plurality of provided cutting dies 700 results in a user using less material, for example, when using the provided cutting dies to cut said material.

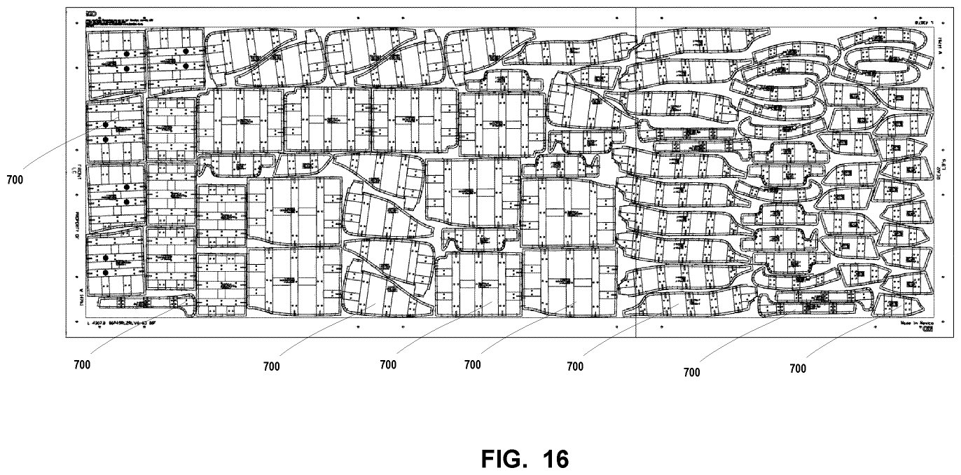

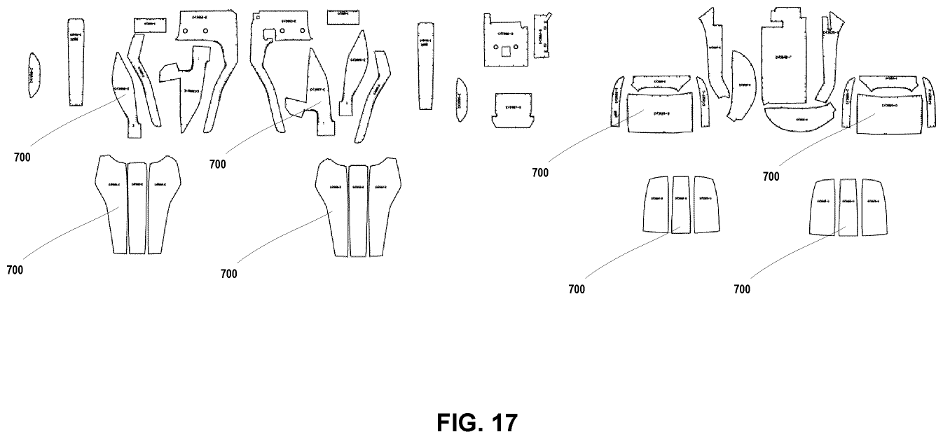

FIGS. 16 and 17 show other examples of a plurality of provided cuttings dies 700 arranged in close proximity to each other (e.g. being spaced apart from each other by a spacing) to be used to simultaneously cut several pieces of a material, such as but not limited to a fabric material. It should be noted that not every cutting die 700 is labelled in these figures for clarity of illustration.

The present technologies has been described here by way of example only. Various modifications and variations may be made to these exemplary embodiments without departing from the scope of the technologies described herein, which is limited only by the appended claims.

What is claimed is:

1. A system for generating an image of a modified desired cutting die, the system comprising:
at least one data storage device storing a set of cutting edge specifications; and
at least one processor communicatively coupled to the at least one data storage device, the at least one processor operable to:
receive at least one image of a desired cutting die;
identify an entire cutting edge of the desired cutting die as shown in the least one image of the desired cutting die, the cutting edge being positioned around a perimeter of the cutting die;
identify at least one feature of the cutting edge of the desired cutting die as shown in the least one image of the desired cutting die;
retrieve a set of cutting edge specifications from the data storage device, the set of cutting edge specifications including a desired tolerance for differences between a shape of the desired cutting die and a shape of a provided cutting die;
based the on the desired tolerance, calculate an offset distance between the cutting edge of the desired cutting die and a cutting edge of the provided cutting die; and
generate an image of a modified desired cutting die based on the offset distance.

2. The system of claim 1, wherein the processor is operable to, when generating the image of the modified desired cutting die, apply the offset distance to the cutting edge of the desired cutting die such that the shape of the modified desired cutting die is smaller than the shape of the desired cutting die.

3. The system of claim 1 or claim 2, wherein the processor is operable to, when generating the image of the modified desired cutting die, modify a position of the one or more features of the cutting edge of the desired cutting die based on the desired tolerance.

4. The system of claim 1 or claim 2, wherein the processor is operable to, when generating the image of the modified desired cutting die, modify a position of the one or more features of the cutting edge of the desired cutting die based on the offset distance.

5. The system of claim 1 or claim 2, wherein the processor is operable to, when generating the image of a modified desired cutting die, modify a feature of the cutting edge of the desired cutting die based on one or more of the offset distance and the desired tolerance.

6. The system of any one of claims 1 to 5, wherein the offset distance is less than the desired tolerance.

7. The system of claim 6, wherein the offset distance is less than about 75% of the desired tolerance, or less than about 60% of the desired tolerance, or about 50% of the desired tolerance.

8. The system of any one of claims 1 to 5, wherein the offset distance is greater than the desired tolerance.

9. A system for providing a cutting die, the system comprising:
at least one data storage device storing a set of cutting edge specifications; and
at least one processor communicatively coupled to the at least one data storage device, the at least one processor operable to:
receive at least one image of a desired cutting die;
identify an entire cutting edge of the desired cutting die as shown in the least one image of the desired cutting die, the cutting edge being positioned around a perimeter of the cutting die;
identify at least one feature of the cutting edge of the desired cutting die as shown in the least one image of the desired cutting die;
retrieve a set of cutting edge specifications from the data storage device, the set of cutting edge specifications including a desired tolerance for differences between a shape of the desired cutting die and a shape of a provided cutting die;
based the on the desired tolerance, calculate an offset distance between the cutting edge of the desired cutting die and a cutting edge of the provided cutting die; and
generate an image of a modified desired cutting die based on the offset distance; and
at least one bending machine operable to provide the provided cutting die based on the generated image of the modified desired cutting die.

10. The system of claim 9, wherein the processor is operable to, when generating the image of the modified desired cutting die, apply the offset distance to the cutting edge of the desired cutting die such that the shape of the modified desired cutting die is smaller than the shape of the desired cutting die.

11. The system of claim 9 or claim 10, wherein the processor is operable to, when generating the image of the modified desired cutting die, modify a position of the one or more features of the cutting edge of the desired cutting die based on the desired tolerance.

12. The system of claim 9 or claim 10, wherein the processor is operable to, when generating the image of the modified desired cutting die, modify a position of the one or more features of the cutting edge of the desired cutting die based on the offset distance.

13. The system of claim 9 or claim 10, wherein the processor is operable to, when generating the image of a modified desired cutting die, modify a feature of the cutting edge of the desired cutting die based on one or more of the offset distance and the desired tolerance.

14. The system of any one of claims 9 to 13, wherein the offset distance is less than the desired tolerance.

15. The system of claim 14, wherein the offset distance is less than about 75% of the desired tolerance, or less than about 60% of the desired tolerance, or about 50% of the desired tolerance.

16. The system of any one of claims 9 to 13, wherein the offset distance is greater than the desired tolerance.

17. A method of providing a cutting die, the method comprising:
receiving at least one image of a desired cutting die;
identifying an entire cutting edge of the desired cutting die as shown in the least one image of the desired cutting die, the cutting edge being positioned around a perimeter of the cutting die;
identifying at least one feature of the cutting edge of the desired cutting die as shown in the least one image of the desired cutting die;
retrieving a set of cutting edge specifications from the data storage device, the set of cutting edge specifications including a desired tolerance for differences between a shape of the desired cutting die and a shape of a provided cutting die;
based the on the desired tolerance, calculating an offset distance between the cutting edge of the desired cutting die and a cutting edge of the provided cutting die;
generating an image of a modified desired cutting die based on the offset distance; and
providing the provided cutting die based on the generated image of the modified desired cutting die.

18. The method of claim 17, wherein generating the image of the modified desired cutting die includes applying the offset distance to the cutting edge of the desired cutting die such that the shape of the modified desired cutting die is smaller than the shape of the desired cutting die.

19. The method of claim 17 or claim 18, wherein generating the image of the modified desired cutting die includes modifying a position of the one or more features of the cutting edge of the desired cutting die based on the desired tolerance.

20. The method of claim 17 or claim 18, wherein generating the image of the modified desired cutting die includes modifying a position of the one or more features of the cutting edge of the desired cutting die based on the offset distance.

21. The method of claim 17 or claim 18, wherein generating the image of a modified desired cutting die includes modifying a feature of the cutting edge of the desired cutting die based on one or more of the offset distance and the desired tolerance.

22. The method of any one of claims 17 to 21, wherein the offset distance is less than the desired tolerance.

23. The method of claim 22, wherein the offset distance is less than about 75% of the desired tolerance, or less than about 60% of the desired tolerance, or about 50% of the desired tolerance.

24. The method of any one of claims 17 to 21, wherein the offset distance is greater than the desired tolerance.

25. A method of providing an image of a modified desired cutting die, the method comprising:
receiving at least one image of a desired cutting die;
identifying an entire cutting edge of the desired cutting die as shown in the least one image of the desired cutting die, the cutting edge being positioned around a perimeter of the cutting die;
identifying at least one feature of the cutting edge of the desired cutting die as shown in the least one image of the desired cutting die;
retrieving a set of cutting edge specifications from the data storage device, the set of cutting edge specifications including a desired tolerance for differences between a shape of the desired cutting die and a shape of a provided cutting die;
based the on the desired tolerance, calculating an offset distance between the cutting edge of the desired cutting die and a cutting edge of the provided cutting die; and
generating an image of a modified desired cutting die based on the offset distance.

26. The method of claim 25, wherein generating the image of the modified desired cutting die includes applying the offset distance to the cutting edge of the desired cutting die such that the shape of the modified desired cutting die is smaller than the shape of the desired cutting die.

27. The method of claim 25 or claim 26, wherein generating the image of the modified desired cutting die includes modifying a position of the one or more features of the cutting edge of the desired cutting die based on the desired tolerance.

28. The method of claim 25 or claim 26, wherein generating the image of the modified desired cutting die includes modifying a position of the one or more features of the cutting edge of the desired cutting die based on the offset distance.

29. The method of claim 25 or claim 26, wherein generating the image of a modified desired cutting die includes modifying a feature of the cutting edge of the desired cutting die based on one or more of the offset distance and the desired tolerance.

30. The method of any one of claims 25 to 29, wherein the offset distance is less than the desired tolerance.

31. The method of claim 30, wherein the offset distance is less than about 75% of the desired tolerance, or less than about 60% of the desired tolerance, or about 50% of the desired tolerance.

32. The method of any one of claims 25 to 29, wherein the offset distance is greater than the desired tolerance.

33. A method of reducing an amount of material that is used to create a plurality of pieces of the material with a cutting machine, the method comprising:
receiving a plurality of images of desired cutting dies;
generating a plurality of images of modified desired cutting dies, each image being based on one respective image of the plurality of images of the desired cutting dies, each modified desired cutting die having a modified boundary being offset inwardly relative to a boundary of the desired cutting die by a calculated offset distance, the calculated offset distance being based on a desired tolerance for differences between a position of the boundary of the desired cutting die and a position of the modified boundary of the modified desired cutting die;
providing, using a bending machine, a plurality of provided cutting dies, each provided cutting die being based on one of the plurality of generated images of the modified desired cutting dies and having a modified footprint that is smaller than a footprint of its respective desired cutting die;
arranging each of the plurality of provided cutting dies on a die board, the total footprint of the plurality of provided cutting dies being smaller than the footprint of the respective desired cutting dies; and
arranging the material with respect to the cutting dies to provide for the cutting machine to cut the material and create the plurality of pieces of the material.
